(19) United States
(12) Patent Application Publication
(10) Pub. No.: US 2020/0209286 A1
(43) Pub. Date: Jul. 2, 2020

(54) GLASS ISOLATION DEVICE AND A MANUFACTURING METHOD THEREOF, AND A CURRENT SENSOR

(71) Applicant: ACEINNA Transducer Systems Co.,Ltd., Wuxi (CN)

(72) Inventors: Dalai Li, Wuxi (CN); Leyue Jiang, Wuxi (CN)

(73) Assignee: ACEINNA Transducer Systems Co., Ltd., Wuxi (CN)

(21) Appl. No.: 16/711,464

(22) Filed: Dec. 12, 2019

(30) Foreign Application Priority Data
Dec. 26, 2018 (CN) 201811600066.9

(51) Int. Cl. G01R 15/20; H05K 1/03; H05K 3/06; H05K 1/18

(52) U.S. Cl. CPC G01R 15/205; H05K 1/0306; H05K 2201/10151; H05K 1/181; H05K 3/06

(57) ABSTRACT

The present invention provides a glass isolation device and a method for manufacturing the glass isolation device, and a current sensor. The current sensor comprises: a conductor, comprising a current input terminal, a current output terminal, a first leg portion connected to the current input terminal, a second leg portion connected to the current output terminal, and a connection portion connected between the first leg portion and the second leg portion; a magnetoresistive sensing device; and an isolation device disposed between the magnetoresistive sensing device and the conductor and comprising an insulating substrate and a conductive thin film formed on the insulating substrate. The conductive thin film is grounded through a wire, and currents on the first leg portion and the second leg portion are in opposite directions. The glass isolation device of the present invention has low raw material and manufacturing costs, and can effectively achieve electrical isolation between a current side and a signal side.

This application claims the priority from CN Application having Serial No. CN 201811600066.9, filed on Dec. 26, 2018, which are incorporated herein by reference for all purposes.

### 1. FIELD OF THE INVENTION

The present invention relates to the technical field of isolation devices, and more particularly relates to a glass isolation device and a manufacturing method thereof, and a current sensor using the isolation device.

### 2. BACKGROUND TECHNIQUE

For current sensors, particularly integrated current sensors, they are always difficult to effectively realize electrical isolation between a current side and a signal side.

Therefore, it is necessary to provide an improved solution to solve the above problems.

### SUMMARY OF THE INVENTION

One object of the present invention is to provide a glass isolation device, which can effectively realize electrical isolation between a current side and a signal side of a current sensor.

Another object of the present invention is to provide a method for manufacturing a glass isolation device, which is capable of effectively realizing electrical isolation between a current side and a signal side of a current sensor.

Still another object of the present invention is to provide a current sensor using an isolation device, which can effectively achieve electrical isolation between a current side and a signal side of the current sensor.

According to one aspect of the present invention, the present invention provides a glass isolation device. The glass isolation device includes: a glass substrate and a conductive thin film formed on the glass substrate.

According to another aspect of the present invention, the present invention provides a current sensor. The current sensor including: a conductor, comprising a current input terminal, a current output terminal, a first leg portion connected to the current input terminal, a second leg portion connected to the current output terminal, and a connection portion connected between the first leg portion and the second leg portion; a magnetoresistive sensing device; and an isolation device disposed between the magnetoresistive sensing device and the conductor and comprising an insulating substrate and a conductive thin film formed on the insulating substrate, wherein the conductive thin film is grounded through a wire, and currents on the first leg portion and the second leg portion are in opposite directions.

According to another aspect of the present invention, the present invention provides a method for manufacturing a glass isolation device. The method comprises: providing a glass wafer; forming a conductive thin film on the glass wafer; and cutting the glass wafer along a plurality of scribe lines to obtain a plurality of glass isolation devices. Each of the glass isolation devices comprises a glass substrate, and a conductive thin film formed on the glass substrate.

Compared with the prior art, the present invention has the advantages that the glass isolation device of the present invention has low raw material and manufacturing costs, and can effectively achieve electrical isolation between a current side and a signal side.

### BRIEF DESCRIPTION OF THE DRAWINGS

The drawings described herein are provided to further understand the present application, and are intended to be a part of this application. In the drawing:

FIG. 1 is a diagram showing a glass isolation device and a manufacturing flow thereof according to a first embodiment of the present invention;

FIG. 2 is a diagram showing a current sensor using the glass isolation device shown in FIG. 1;

FIG. 3 is a diagram showing the glass isolation device and the manufacturing flow thereof according to a second embodiment of the present invention; and

FIG. 4 is a diagram showing a current sensor using the glass isolation device shown in FIG. 3.

### DETAILED DESCRIPTION OF THE INVENTION

In order to make the schemes and advantages of the embodiments of the present invention clearer, the exemplary embodiments of the present invention are further described in detail with reference to the accompanying drawings. Obviously, the described embodiments are only part of the embodiments of the present invention, and not all exhaustive embodiments. It should be noted that the embodiments of the present invention and the features of the embodiments may be combined with each other in case of no conflict.

The present invention provides a glass isolation device, which can effectively realize electrical isolation between a current side and a signal side of a current sensor.

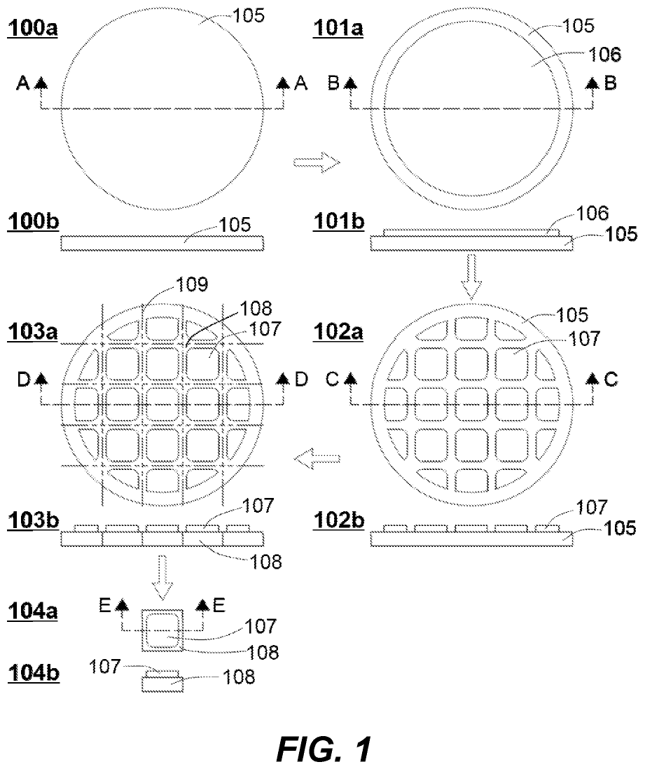

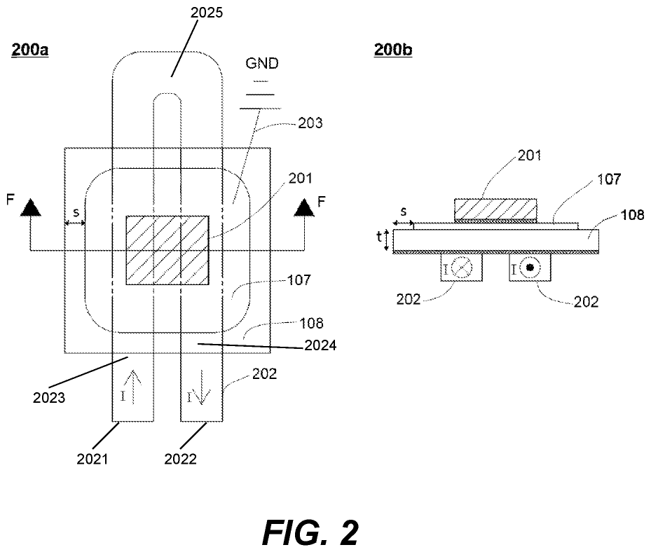

FIG. 1 is a diagram showing a glass isolation device and a manufacturing flow thereof according to a first embodiment of the present invention. FIG. 2 is a diagram showing a current sensor using the glass isolation device shown in FIG. 1. In FIG. 1, 104a is a top view of a single glass isolation device, and 104b is a cross-sectional schematic diagram along a section line E-E. As shown in 104a and 104b in FIG. 1, the glass isolation device includes a glass substrate 108 and a conductive thin film 107 formed on the glass substrate 108. In conjunction with FIG. 2, an edge of the glass substrate 108 is spaced from an edge of the conductive thin film 107 at a predetermined distance s.

A method for manufacturing the glass isolation device is provided according to the first embodiment of the present invention. The method may manufacture a glass isolation device capable of effectively realizing electrical isolation between a current side and a signal side of a current sensor. As shown in FIG. 1, the method for manufacturing the glass isolation device includes the following operations.

Firstly, a glass wafer 105 is provided. In FIG. 1, 100a is a top view of the glass wafer 105, and 100b is a cross-sectional view of the glass wafer 105 along a section line A-A.

A conductive thin film 106 is formed on the glass wafer 105. In FIG. 1, 101a is a top view of the glass wafer 105 with the conductive thin film 106, and 101b is a cross-sectional view of the glass wafer 105 in 101a along a section line B-B.

Then, an etching process is preformed on the conductive thin film 106 to obtain a patterned conductive thin film 107. In FIG. 1, 102a is a top view of the glass wafer 105 with the patterned conductive thin film 107, and 102b is a cross-sectional view along a section line C-C in 102a.

Finally, the glass wafer 105 is cut along a plurality of scribe lines 109 to obtain a plurality of glass isolation devices. Each glass isolation device includes the glass substrate 108, and the conductive thin film 107 formed on the glass substrate 108. In FIG. 1, 103a is a top view of the glass wafer after being cut, and 103b is a cross-sectional view along a section line D-D in 103a.

The present invention further provides a current sensor using the glass isolation device shown in FIG. 1. The glass isolation device may effectively realize electrical isolation between a current side and a signal side of the current sensor.

In FIG. 2, 200a is a top view of the current sensor, and 200b is a cross-sectional schematic diagram along a section line F-F. As shown in 200a and 200b in FIG. 2, the current sensor includes a conductor 202, a magnetoresistive sensing device 201 and a glass isolation device. The conductor 202 includes a current input terminal 2021, a current output terminal 2022, a first leg portion 2023 connected to the current input terminal, a second leg portion 2024 connected to the current output terminal, and a connection portion 2025 connected between the first leg portion and the second leg portion. Currents on the first leg portion and the second leg portion are in opposite directions. Specifically, the conductor 202 is a U-shaped conductor. The magnetoresistive sensing device 201 is located on one side of the conductor 202, and the glass isolation device is disposed between the magnetoresistive sensing device 201 and the conductor 202. The structure of the glass isolation device is consistent with the structure of the glass isolation device shown in FIG. 1. The conductive thin film 107 is grounded through a wire 203, so that the influence on the output of the magnetoresistive sensing device 201 due to voltage fluctuation of the U-shaped conductor 202 may be eliminated. An edge of the glass substrate 108 is spaced from an edge of the conductive thin film 107 at a predetermined distance s. The glass substrate 108 has a thickness t. Therefore, a dielectric distance between the U-shaped conductor 202 and the magnetoresistive sensing device 201 is t+s, and the dielectric strength between the U-shaped conductor 202 and the magnetoresistive sensing device 201 is more than 5000 V. A longer dielectric distance may achieve higher dielectric strength. Each magnetoresistive sensor is an anisotropic magnetoresistive based sensor, a giant magnetoresistive based sensor, a tunneling magnetoresistive based sensor or a Hall based sensor.

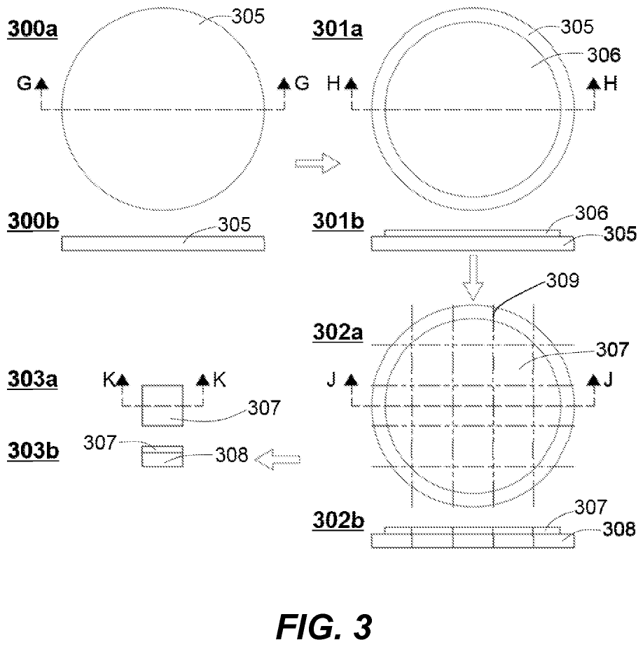

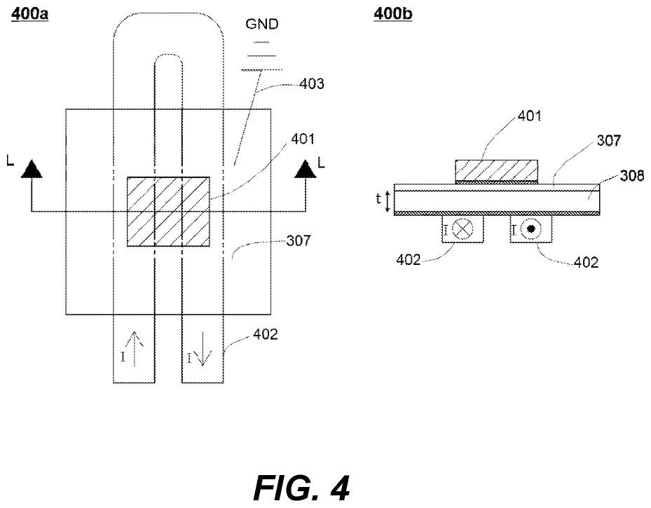

FIG. 3 is a diagram showing the glass isolation device and the manufacturing flow thereof according to a second embodiment of the present invention. FIG. 4 is a diagram showing a current sensor using the glass isolation device shown in FIG. 3. In FIG. 3, 303a is a top view of a single glass isolation device, and 303b is a cross-sectional view along a section line K-K. As shown in 303a and 303b in FIG. 3, the glass isolation device includes a glass substrate 308, and a conductive thin film 307 formed on the glass substrate 308. The conductive thin film 307 may be grounded through a wire. As shown in FIG. 4, an edge of the glass substrate 308 is aligned with an edge of the conductive thin film 307. That is, the conductive thin film 306 is not patterned in the second embodiment.

A method for manufacturing the glass isolation device is provided according to the second embodiment of the present invention. As shown in FIG. 3, the method for manufacturing the glass isolation device includes the following operations.

A glass wafer 305 is provided. In FIG. 3, 300a is a top view of the glass wafer 305, and 300b is a cross-sectional view of the glass wafer 305 along a section line G-G.

A conductive thin film 306 is formed on the glass wafer 305. In FIG. 3, 301a is a top view of the glass wafer 305 with the conductive thin film 306, and 301b is a cross-sectional view of the glass wafer 305 in 301a along a section line H-H.

The glass wafer 305 is cut along a plurality of scribe lines 309 to obtain a plurality of glass isolation devices. Each glass isolation device includes a glass substrate 308, and the conductive thin film 307 formed on the glass substrate 308. In FIG. 3, 303a is a top view of the glass wafer after being cut, and 303b is a cross-sectional view of the glass isolation device in 303a along a section line K-K.

In FIG. 4, 400a is a top view of the current sensor, and 400b is a cross-sectional schematic diagram along a section line L-L. As shown in 400a and 400b in FIG. 4, the current sensor includes a conductor 402, a magnetoresistive sensing device 401 and a glass isolation device. The structure of the conductor 402 in FIG. 4 is the same as the structure of the conductor 202 in FIG. 2, so no repeated descriptions are provided here. The conductor 402 is a U-shaped conductor. The glass isolation device is disposed between the magnetoresistive sensing device 401 and the conductor 402. The conductive thin film 307 is grounded through a wire 403, so that the influence on the output of the magnetoresistive sensing device 401 due to voltage fluctuation of the U-shaped conductor 402 may be eliminated. An edge of the glass substrate 408 is aligned with an edge of the conductive thin film 407. The glass substrate 408 has a thickness t. Therefore, a dielectric distance between the U-shaped conductor 402 and the magnetoresistive sensing device 401 is t, and the dielectric strength between the U-shaped conductor 402 and the magnetoresistive sensing device 401 is more than 5000 V. Each magnetoresistive sensor is an anisotropic magnetoresistive based sensor, a giant magnetoresistive based sensor, a tunneling magnetoresistive based sensor or a Hall based sensor.

In one alternative embodiment, the current sensors in FIG. 2 and FIG. 4 may also use non-glass isolation devices. For example, a magnesium oxide substrate, a ceramic substrate or a silicon nitride substrate may replace the glass substrate as an insulating substrate of the isolation device and can also effectively realize electrical isolation between a current side and a signal side of the current sensor. Compared with an insulating substrate made of other materials, the glass substrate has the advantages of low cost, easy manufacture, good isolation and the like.

In the present invention, unless otherwise specified, the terms indicating electrical connection, such as “connect”, indicate direct or indirect electrical connection.

Obviously, a person skilled in the art may make various changes and variations to the application without departing from the spirit and scope of the application. Thus, if these modifications and variations of this application fall within the scope of the claims and their equivalent technologies, the application is also intended to include these changes and variations.

What is claimed is:

1. A glass isolation device, comprising:
a glass substrate; and
a conductive thin film formed on the glass substrate.

2. The glass isolation device according to claim 1, wherein
an edge of the glass substrate is aligned with an edge of the conductive thin film, or
an edge of the glass substrate is spaced from an edge of the conductive thin film at a predetermined distance.

3. A current sensor, comprising:
a conductor, comprising a current input terminal, a current output terminal, a first leg portion connected to the current input terminal, a second leg portion connected to the current output terminal, and a connection portion connected between the first leg portion and the second leg portion;
a magnetoresistive sensing device; and
an isolation device disposed between the magnetoresistive sensing device and the conductor and comprising an insulating substrate and a conductive thin film formed on the insulating substrate, wherein the conductive thin film is grounded through a wire, and currents on the first leg portion and the second leg portion are in opposite directions.

4. The current sensor according to claim 3, wherein
the conductor is a U-shaped conductor;
an edge of the insulating substrate is aligned with an edge of the conductive thin film, or
an edge of the insulating substrate is spaced from an edge of the conductive thin film at a predetermined distance.

5. The current sensor according to claim 3, wherein the magnetoresistive sensing device includes a first magnetoresistive sensor disposed on one side of the first leg portion and a second magnetoresistive sensor disposed on one side of the second leg portion, the first magnetoresistive sensor and the second magnetoresistive sensor are integrated on the same chip, and each magnetoresistive sensor is an anisotropic magnetoresistive based sensor, a giant magnetoresistive based sensor, a tunneling magnetoresistive based sensor or a Hall based sensor.

6. The current sensor according to claim 3, wherein
the insulating substrate is a glass substrate, a magnesium oxide substrate, a ceramic substrate or a silicon nitride substrate.

7. A method for manufacturing a glass isolation device, comprising:
providing a glass wafer;
forming a conductive thin film on the glass wafer; and
cutting the glass wafer along a plurality of scribe lines to obtain a plurality of glass isolation devices, wherein each of the glass isolation devices comprises a glass substrate, and a conductive thin film formed on the glass substrate.

8. The method according to claim 7, wherein after forming a conductive thin film on the glass wafer and before cutting the glass wafer along a plurality of scribe lines, the method further comprises:
performing an etching process on the conductive thin film to obtain a patterned conductive thin film.
